(19) United States
(12) Patent Application Publication
(10) Pub. No.: US 2022/0077379 A1
(43) Pub. Date: Mar. 10, 2022

(54) PIEZOELECTRIC DEVICE WITH PIEZOELECTRIC ELONGATE NANO-OBJECTS

(71) Applicants: COMMISSARIAT A L'ENERGIE ATOMIQUE ET AUX ENERGIES ALTERNATIVES, Paris (FR); UNIVERSITE GRENOBLE ALPES, Saint Martin D'Heres (FR); CENTRE NATIONAL DE LA RECHERCHE SCIENTIFIQUE, Paris (FR); INSTITUT POLYTECHNIQUE DE GRENOBLE, Grenoble (FR)

(72) Inventors: Clément LAUSECKER, Ballan Miré (FR); Xavier BAILLIN, Grenoble (FR); Vincent CONSONNI, Montbonnot-Saint-Martin (FR); Bassem SALEM, Sassenage (FR)

(73) Assignees: COMMISSARIAT A L'ENERGIE ATOMIQUE ET AUX ENERGIES ALTERNATIVES, PARIS (FR); UNIVERSITE GRENOBLE ALPES, SAINT MARTIN D'HERES (FR); CENTRE NATIONAL DE LA RECHERCHE SCIENTIFIQUE, PARIS (FR); INSTITUT POLYTECHNIQUE DE GRENOBLE, GRENOBLE (FR)

(21) Appl. No.: 17/468,593

(22) Filed: Sep. 7, 2021

(30) Foreign Application Priority Data
Sep. 4, 2020 (FR) 20/09016

(51) Int. Cl. H01L 41/09; H01L 41/187; H01L 41/22; H01L 41/113

(52) U.S. Cl. CPC H01L 41/0986; H01L 41/113; H01L 41/22; H01L 41/187

(57) ABSTRACT

The piezoelectric device includes a first electrode, a second electrode, piezoelectric elongate nano-objects in contact with the first electrode, and extending between the first electrode and the second electrode, a first layer of an electrically-insulating first material, the first layer surrounding a first longitudinal portion of each of the piezoelectric elongate nano-objects, a second layer of an electrically-insulating second material, the second layer surrounding a second longitudinal portion of each of the piezoelectric elongate nano-objects. The first layer is arranged between the first electrode and the second layer. The thickness of the first layer is strictly smaller than the thickness of the second layer. The first material has a Young's modulus strictly higher than the Young's modulus of the second material.

### TECHNICAL FIELD OF THE INVENTION

The technical field of the invention concerns piezoelectricity and in particular a piezoelectric device, such as for example a piezoelectric nanogenerator, including piezoelectric elongate nano-objects such as for example nanowires.

### STATE OF THE ART

A piezoelectric nanogenerator, also known under the abbreviation PENG, can generate an electric voltage from mechanical vibrations applied to the piezoelectric nanogenerator. The piezoelectric nanogenerator is a transducer. The piezoelectric nanogenerators are of great interest in the development of low-power portable electronic systems as they could be miniaturized and because they allow making these portable electronic systems energy self-sufficient.

The piezoelectric nanogenerator may be formed according to vertical integrated nanogenerator type, also known under the abbreviation «VING», architecture. To form the nanogenerator according to this VING-type architecture, an array of piezoelectric nanowires arranged orthogonally with respect to a substrate of the nanogenerator is commonly used. This array of piezoelectric nanowires is interposed between two metallic electrodes and is embedded in a polymer matrix. The piezoelectric nanowires allow significantly increasing the efficiency of the nanogenerator in comparison with a nanogenerator including a layer of a piezoelectric material arranged between two electrodes. To form these piezoelectric nanowires, a piezoelectric material could advantageously be used like a zinc oxide such as ZnO or a gallium nitride such as GaN, such a piezoelectric material combines good piezoelectric properties and the capability of forming piezoelectric nanowires spontaneously by various growth techniques. Typically, these growth techniques are chemical vapor deposition (also known under the abbreviation «CVD») or molecular beam epitaxy (also known under the abbreviation MBE). Furthermore, the zinc oxide may be synthesized by low-temperature processes, that is to say by processes implemented at temperature for example lower than or equal to 200° C., such as chemical bath deposition (also known under the abbreviation «CBD»), hydrothermal synthesis (also known under the abbreviation «HS») or electrochemical deposition (also known under the abbreviation «ECD»). The polymer matrix is intended to ensure the integrity of the array of nanowires during the use of the PENG by stabilizing the vertical alignment of the piezoelectric nanowires. Moreover, this matrix must be flexible enough to enable the deformation of the array of piezoelectric nanowires by the effect of mechanical vibrations in order to ensure the generation of a desired electric voltage by the PENG. Thus, a tradeoff must be found between the good strength of the array of piezoelectric nanowires and the freedom of deformation of the piezoelectric nanowires of the array. However, the tradeoff is generally achieved by favoring the deformation capability of the piezoelectric nanowires secured to the substrate at the expense of a good strength of the array of piezoelectric nanowires.

The document «Self-powered nanowire devices» of Sheng Xu et al. published in Nature Nanotechnology, vol 5, May 2010, pages 366 to 373, is a document describing zinc oxide nanowires arranged between two electrodes and formed on a silicon wafer covered with gold. Between the two electrodes, a polymer matrix of poly(methyl methacrylate) embeds the nanowires. Such a polymer matrix does not allows filling the following contradictory functions simultaneously:
be rigid enough to ensure the proper mechanical holding of the nanowires with respect to the silicon wafer,
be flexible enough to ensure the free deformation of the nanowires.

In fact, in this instance, the matrix rather promotes the deformation of the nanowires at the expense of their holding/strength with respect to the silicon wafer.

The U.S. Pat. No. 8,003,982 B2 describes different embodiments of an electric generator comprising zinc oxide nanowires. According to one embodiment, the zinc oxide nanowires are obtained by growing starting from the catalyst particles placed on a substrate, and a deformable layer, such as a layer of an organic polymer, is deposited on the substrate so that to surround each of the zinc oxide nanowires at a predetermined level in order to hold these nanowires to avoid detachment thereof with respect to the substrate. According to another embodiment, zinc oxide nanowires are obtained by growing starting from a gold film belonging to a stack comprising successively a substrate, a titanium film and the gold film. According to this other embodiment, a layer of an elastic and soft flexible polymer is formed by embedding the nanowires before freeing longitudinal ends thereof having to come into contact with a metal layer, this polymer layer allows promoting the deformation of the nanowires but at the expense of holding thereof with respect to the substrate.

### OBJECT OF THE INVENTION

The invention aims at improving the robustness of a piezoelectric device while enabling this piezoelectric device to have a satisfactory effectiveness.

To this end, the invention relates to a piezoelectric device including:
a first electrode,
a second electrode,
piezoelectric elongate nano-objects in contact with the first electrode, the piezoelectric elongate nano-objects extending between the first electrode and the second electrode,
a first layer of a first material, the first material being electrically-insulating, the first layer surrounding a first longitudinal portion of each of the piezoelectric elongate nano-objects,
a second layer of a second material, the second material being electrically-insulating, the second layer surrounding a second longitudinal portion of each of the piezoelectric elongate nano-objects.

The first layer is arranged between the first electrode and the second layer. The thickness of the first layer is strictly smaller than the thickness of the second layer. The first material has a Young's modulus strictly higher than the Young's modulus of the second material.

The use of the first and second layers having different thicknesses and respectively formed by a first material and by a second material with different Young's moduli allows ensuring different holdings of the piezoelectric elongate nano-objects between the first and second electrodes. This allows obtaining a structure ensuring a good strength of the piezoelectric elongate nano-objects, and therefore of an array of nano-objects formed by these piezoelectric elongate nano-objects, while preserving a satisfactory freedom of deformation of the piezoelectric elongate nano-objects.

The piezoelectric device may further include one or more of the following features:
the Young's modulus of the first material is higher than or equal to 5 GPa;
the Young's modulus of the first material is higher than or equal to 25 GPa;
the first material is selected amongst: a hydrogen silsesquioxane, silicon dioxide, alumina and a silicon nitride;
the Young's modulus of the second material is strictly lower than 5 GPa;
the second material is selected amongst: poly(methyl methacrylate), a hydrogen silsesquioxane, a SU-8 resin, a polydimethylsiloxane, a parylene C, and a resin based on an organic polymer and containing silicon;
each piezoelectric elongate nano-object has an aspect ratio equal to L/D, with L being the length of said piezoelectric elongate nano-object and D being the maximum transverse dimension of said piezoelectric elongate nano-object, the aspect ratio being higher than or equal to 5 and D being smaller than or equal to 500 nm;
D is smaller than or equal to 50 nm;
the piezoelectric device is such that: the length of each of the piezoelectric elongate nano-objects is strictly larger than the sum of the thickness of the first layer and of the thickness of the second layer, the second electrode is in contact with the piezoelectric elongate nano-objects, at least one of the first and second electrodes forms a Schottky contact with the piezoelectric elongate nano-objects;
the length of each of the piezoelectric elongate nano-objects is strictly smaller than the sum of the thickness of the first layer and of the thickness of the second layer, and the second electrode is at a distance from the piezoelectric elongate nano-objects;
each of the piezoelectric elongate nano-objects includes a first longitudinal end and a second longitudinal end, the first longitudinal ends being in contact with the first electrode and the second longitudinal ends being in contact with a third layer of an electrically-insulating material, the third layer connecting the second longitudinal ends to the second electrode;
the electrically-insulating material of the third layer has a relative permittivity higher than or equal to 3.9;
the electrically-insulating material of the third layer is selected amongst: an aluminum oxide, a silicon nitride and a hafnium oxide;
the piezoelectric elongate nano-objects are zinc oxide or gallium nitride nanowires;
the piezoelectric elongate nano-objects are zinc oxide or gallium nitride nanotubes;
the piezoelectric elongate nano-objects are nanowires each including a core made of zinc oxide or gallium nitride, and an electrical passivation layer arranged on said core;
the thickness of the first layer is smaller than or equal to 20% of the length of the piezoelectric elongate nano-objects;
the piezoelectric device includes a substrate, and the first electrode is arranged on the substrate or is formed by the substrate;
the piezoelectric device forms a pressure sensor, a piezoelectric nanogenerator or a haptic device.

The invention also relates to a method for manufacturing a piezoelectric device in particular as described. The manufacturing method includes:
a step of forming piezoelectric elongate nano-objects on a first electrode,
a step of forming a first layer of a first material so that the formed first layer surrounds a first longitudinal portion of each of the piezoelectric elongate nano-objects, the first material being electrically-insulating,
a step of forming a second layer of a second material so that the formed second layer surrounds a second longitudinal portion of each of the piezoelectric elongate nano-objects, the second material being electrically-insulating,
a step of forming a second electrode, the formed second electrode being arranged so that the piezoelectric elongate nano-objects extend between the first electrode and the second electrode.

The first layer is arranged between the first electrode and the second layer, the thickness of the formed first layer is strictly smaller than the thickness of the formed second layer, and the first material has a Young's modulus strictly higher than the Young's modulus of the second material.

Other advantages and features will come out from the following detailed description.

### BRIEF DESCRIPTION OF THE DRAWINGS

The invention will be understood upon reading the following detailed description, provided only as a non-limiting example and made with reference to the appended drawings listed hereinbelow.

FIG. 1 illustrates, according to a sectional view, a piezoelectric device according to an example of a first embodiment of the invention.

FIG. 2 illustrates, according to a sectional view, the piezoelectric device according to an example of a second embodiment of the invention.

FIG. 3 illustrates, according to a sectional view, the piezoelectric device according to an example of a third embodiment of the invention.

FIG. 4 illustrates, according to a sectional view, the result of a step of forming piezoelectric elongate nano-objects during the manufacture of the piezoelectric device.

FIG. 5 illustrates, according to a sectional view, the result of a step of forming a first layer of a first material during the manufacture of the piezoelectric device.

FIG. 6 illustrates, according to a sectional view, the result of a step of forming a second layer of a second material during the manufacture of the piezoelectric device according to the first embodiment.

FIG. 7 illustrates, according to a sectional view, the result of a step of forming the second layer during the manufacture of the piezoelectric device according to the second embodiment.

FIG. 8 illustrates, according to a sectional view, how the second layer and a third layer of the piezoelectric device could be formed in order to form the piezoelectric device according to the third embodiment.

FIG. 9 illustrates, according to a sectional view, a variant of the piezoelectric device according to the first embodiment.

FIG. 10 illustrates, according to a sectional view, a variant of the first embodiment, according to this variant the piezoelectric device includes nanowires with a core-shell structure.

FIG. 11 illustrates, according to a sectional view, a variant of the second embodiment, according to this variant the piezoelectric device includes nanowires with a core-shell structure.

FIG. 12 illustrates, according to a sectional view, a variant of the third embodiment, according to this variant the piezoelectric device includes nanowires with a core-shell structure.

In these figures, the same reference numerals are used to refer to the same elements.

### DETAILED DESCRIPTION

By «comprised between two values», it should be understood that the bounds defined by these two values are included within the considered range of values.

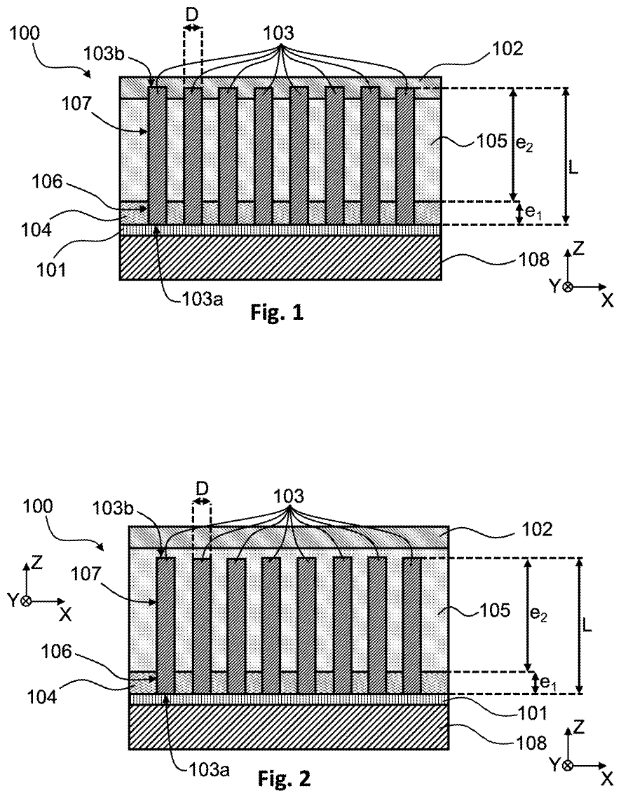

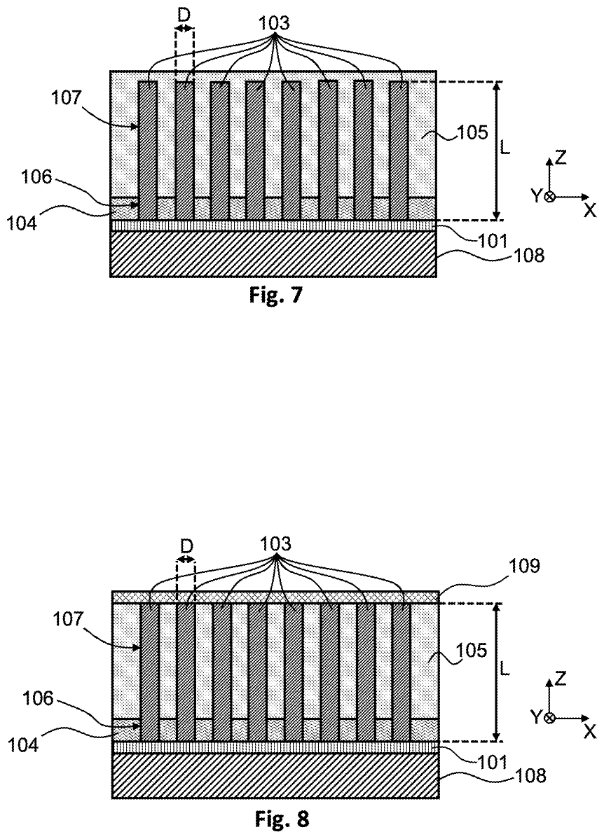

For the needs of the present description, an orthonormal reference frame is now defined with the axes X, Y and Z, hereinafter referred to as the reference frame XYZ, representing the reference base of the piezoelectric device 100, this reference frame XYZ is represented in FIGS. 1 to 12. In particular, the lower and upper notions should be understood with reference to the axis Z which is directed upwards.

By «a few» followed by a unit (such as for examples a few nanometers, a few tens of nanometers or a few hundreds of nanometers), it should preferably be understood in the present description that the corresponding value (that of the considered quantity associated to «a few») could be comprised between a value strictly higher than one time the amount and a value equal to nine times the amount. In this respect, for example, by a few tens of nanometers (nm), it should be understood a value strictly higher than 10 nanometers and lower than or equal to 90 nanometers.

The piezoelectric device 100, a first, second and third embodiments thereof are represented respectively in FIGS. 1 to 3, includes a first electrode 101, a second electrode 102 and piezoelectric elongate nano-objects 103.

In the field, the first electrode 101 is commonly called lower electrode and the second electrode 102 is commonly called upper electrode. Typically, each of the first and second electrodes 101, 102 may have a thickness comprised between a few nanometers and a few hundreds of nanometers. Preferably, the second electrode 102 is arranged facing the first electrode 101 and is for example arranged right above this first electrode 101 as show in FIGS. 1 to 3 in the referential of the reference frame XYZ.

In particular, the piezoelectric elongate nano-objects 103 form an array of nano-objects. The piezoelectric elongate nano-objects 103 are in contact with the first electrode 101. The piezoelectric elongate nano-objects 103 extend between the first electrode 101 and the second electrode 102.

The piezoelectric device 100 includes a first layer 104 of a first material and a second layer 105 of a second material. The first material is electrically-insulating, and the second material is electrically-insulating, meaning that the first and second layers 104, 105 are electrically-insulating. The first layer 104 surrounds a first longitudinal portion 106 of each of the piezoelectric elongate nano-objects 103. The second layer 105 surrounds a second longitudinal portion 107 of each of the piezoelectric elongate nano-objects 103. The first layer 104 is arranged between the first electrode 101 and the second layer 105. This results in that the first and second layers 104, 105 are arranged between the first and second electrodes 101, 102. The first material has a Young's modulus strictly higher than the Young's modulus of the second material, and the thickness of the first layer 104 is strictly smaller than the thickness of the second layer 105. The condition regarding the thicknesses of the first and second layers 104, 105 has the advantage of limiting the thickness of the first layer 104, for example to that one necessary to obtain a good strength of the piezoelectric elongate nano-objects 103 via this first layer 104 and the advantage of ensuring holding of these piezoelectric elongate nano-objects 103 to the first electrode 101 and, where appropriate, to a substrate 108 in particular on which the first electrode 101 could be arranged. Thus, the first layer 104 ensures mechanical holding of the piezoelectric elongate nano-objects 103 and is configured in particular to: consolidate the array of piezoelectric elongate nano-objects 103 at the base of each of the piezoelectric elongate nano-objects 103 in particular to avoid detachment thereof with respect to the first electrode 101 and, where appropriate, with respect to the substrate 108; and ensures the integrity of the piezoelectric elongate nano-objects 103 by stabilizing the alignment thereof. The second layer 105 has the advantage of enabling holding of the piezoelectric elongate nano-objects 103 while enabling the deformation thereof during use of the piezoelectric device. Thus, the first and second layers 104, 105 have the advantage of ensuring a satisfactory strength of the piezoelectric elongate nano-objects 103 at the level of their first longitudinal portion 106 while allowing promoting the deformation of the piezoelectric elongate nano-objects 103 at the level of their second longitudinal portion 107 and the advantage of avoiding any direct contact between the piezoelectric elongate nano-objects 103 for example:
when the piezoelectric device 100 is subjected to a load to enable the generation of a potential difference within the piezoelectric elongate nano-objects 103 impacted by this load, or
when the first and second electrodes 101, 102 of the piezoelectric device 100 are used to subject the piezoelectric elongate nano-objects 103 to an electric field to intentionally deform them.

This results in that the piezoelectric device 100 has a better robustness while having a satisfactory efficiency.

In particular, the first layer 104 is in contact with the first longitudinal portions 106 surrounded thereby. In other words, the first layer 104 embeds the first longitudinal portions 106.

In particular, the second layer 105 is in contact with the second longitudinal portions 107 surrounded thereby. In other words, the second layer 105 embeds the second longitudinal portions 107.

Thus, the first and second layers 104, 105 may form two distinct matrices each participating in the mechanical holding of the piezoelectric elongate nano-objects 103. These two distinct matrices are stacked and have different mechanical properties.

The first layer 104 and the second layer 105 may have lateral dimensions, measured orthogonally to the axis Z that is to say orthogonally to the thickness direction of the first layer 104 and to the thickness direction of the second layer 105, which are similar or identical.

In particular, the first and second layers 104, 105 are stacked and in contact. Thus, the second layer 105 is preferably arranged on the first layer 104. In this case, for each piezoelectric elongate nano-object 103, its second longitudinal portion 107 is arranged in the continuation of its first longitudinal portion 106. This allows control the electrical insulation of the piezoelectric elongate nano-objects 103 according to their length.

The piezoelectric elongate nano-objects 103 are preferably so-called «integrated vertically» meaning that, in the reference frame XYZ, the direction of extension of each of the piezoelectric elongate nano-objects 103 is preferably vertical and parallel to the axis Z. In this case, the first and second electrodes 101, 102 are so-called «horizontal» in the reference frame XYZ and each is arranged in a plane parallel to the plane defined by the axes X and Y.

As shown in particular in FIGS. 1 to 3, each piezoelectric elongate nano-object 103 may include:
a first longitudinal end 103a in contact with the first electrode 101 in particular at the level of the aforementioned base of said piezoelectric elongate nano-object 103, preferably the first longitudinal portion 106 of the piezoelectric elongate nano-object 103 extends from the first longitudinal end 103a towards the second electrode 102,
a second longitudinal end 103b opposite to the first longitudinal end 103a and located at a distance, with respect to the first electrode 101, equal to the length L of the considered piezoelectric elongate nano-object 103.

In other words, for each piezoelectric elongate nano-object 103, its first and second longitudinal ends 103a, 103b are opposite in the longitudinal direction of said piezoelectric elongate nano-object 103, the second longitudinal end 103b being proximate to the second electrode 102 while the first longitudinal end 103a is in contact with the first electrode 101.

In the present description, each piezoelectric elongate nano-object 103 has, besides its length L, a maximum transverse dimension D strictly smaller than its length L (FIGS. 1 to 12). The length L of each piezoelectric elongate nano-object 103 may be comprised between 100 nm and 10 μm. In particular, the maximum transverse dimension D of each piezoelectric elongate nano-object 103, also called diameter in the technical field of the invention is at a nanometric scale. Thus, the maximum transverse dimension D may be comprised between a few nanometers and a few hundreds of nanometers. Preferably, the maximum transverse dimension D of each of the piezoelectric elongate nano-objects 103 is smaller than or equal to 500 nm.

The piezoelectric elongate nano-objects 103 may be nanowires or nanotubes. The nanowires may be «simple» nanowires, that is to say each forming an elongate element formed by one single material such as a gallium nitride nanowire (such as a GaN nanowire) or a zinc oxide nanowire (such as a ZnO nanowire), or be nanowires having a core-shell structure. This core-shell structure type allows increasing even more the energy produced by the nanogenerator in comparison with a structure with «simple» nanowires.

By «piezoelectric elongate nano-object 103», it should be understood that the piezoelectric elongate nano-object 103 includes a piezoelectric material such as for example gallium nitride or zinc oxide. In particular, the piezoelectric elongate nano-object 103 is totally or partially formed by this piezoelectric material. Thus, when subjected to a load causing deformation thereof, the piezoelectric elongate nano-object 103 allows obtaining within the piezoelectric elongate nano-object 103 a potential difference allowing generating an electrical signal. Of course, conversely, if a suited electric field is applied to the piezoelectric elongate nano-objects 103 by the first and second electrodes 101, 102, then the piezoelectric elongate nano-objects 103 will be deformed.

Each of the piezoelectric elongate nano-objects 103 has a wurtzite-type hexagonal crystalline structure such that the piezoelectric response of said piezoelectric elongate nano-object 103 is the highest in the direction <0001> (corresponding in particular to the piezoelectric coefficient d₃₃) also called «C axis».

Preferably, the piezoelectric elongate nano-objects 103 are zinc oxide or gallium nitride nanowires, such nanowires are «simple» nanowires as mentioned before. Such nanowires have the advantage of having a wurtzite-type crystalline structure so as to obtain, for each of the nanowires, the piezoelectric response mentioned before. These nanowires being preferably obtained by growth, each nanowire has the advantage that its growth is performed spontaneously in the direction <0001> which then corresponds to the longitudinal axis of said nanowire. Preferably, the longitudinal axes of the nanowires are substantially vertical (in the reference base of the piezoelectric device 100) with an angle with respect to the normal to the plane of the substrate 108 strictly smaller than 25 degrees. Advantageously, the longitudinal axes of the nanowires are orthogonal to the planes of the first and second layers 104, 105, to the planes of the first and second electrodes 101, 102, and, where appropriate, to the plane of the substrate 108 of the piezoelectric device on which the first electrode 101, the first layer 104, the second layer 105, and the second electrode 102 are successively stacked.

Preferably, each piezoelectric elongate nano-object 103 has an aspect ratio equal to L/D, with L being the length of said piezoelectric elongate nano-object 103 and D being the maximum transverse dimension of said piezoelectric elongate nano-object 103 as mentioned before. This aspect ratio is higher than or equal to 5 and the maximum transverse dimension D of each of the piezoelectric elongate nano-objects 103 is smaller than or equal to 500 nm and advantageously smaller than or equal to 50 nm in order to accentuate the piezoelectric effect of the considered piezoelectric elongate nano-object 103. The known analytical expression of the expression of the potential generated by a piezoelectric elongate nano-object 103 shows that this potential is proportional to the ratio L/D and inversely proportional to D. Hence, it is advantageous to have piezoelectric elongate nano-objects 103 having the smallest possible maximum lateral dimension D and the largest possible length L as shown for example in the document «Performance Optimization of Vertical Nanowire-based Piezoelectric Nanogenerators» of Hinchet et al. published in Advanced Functional Materials 2014, 24, 971-977.

The first electrode 101 may be formed by at least one metallic layer or by a doped semiconductor layer allowing, depending on the use of the piezoelectric device 100:
ensuring the recovery of electric charges if the piezoelectric device 100 is subjected to a load allowing obtaining an electric potential difference in one or several piezoelectric elongate nano-object(s) 103, or
participating with the second electrode 102 in subjecting the piezoelectric elongate nano-objects 103 to an electric field in order to deform them.

According to a particular example that is not represented in the figures, the first electrode 101 may be formed by a stack of first and second metallic layers. The first metallic layer may be in contact with the substrate 108 to promote attaching of the second metallic layer and therefore anchor the second metallic layer with respect to the substrate 108. In this case, the first metallic layer may be a layer of titanium, chromium or titanium nitride, and the first metallic layer may have a thickness of a few tens of nanometers. The second metallic layer may be a layer of gold, or platinum, and the second metallic layer may have a thickness comprised between a few tens of nanometers and a few hundreds of nanometers. This second metallic layer, arranged on the first metallic layer and in contact with the piezoelectric elongate nano-objects 103, is adapted to ensure a desired electrical conductivity function and also to serve as a nucleation layer of the piezoelectric elongate nano-objects 103 during the manufacture of the piezoelectric device 100.

The interface between the first electrode 101 and the piezoelectric elongate nano-objects 103 may be either of the ohmic type or of the Schottky type. For piezoelectric elongate nano-objects 103 formed by zinc oxide nanowires, the first electrode 101, preferably monocrystalline, may be formed by:
a layer of zinc oxide, preferably monocrystalline, a layer of zinc oxide, preferably monocrystalline, doped with aluminum also known under the abbreviation AZO and for which the doping may be carried out at least to a determined depth, a layer of indium oxide doped with tin also known under the abbreviation ITO, or a layer of tin oxide doped with fluorine (also known under the abbreviation FTO) so that the first electrode 101 forms an ohmic contact with the piezoelectric elongate nano-objects 103, or
a layer of gold or a layer of platinum so that the first electrode 101 forms a Schottky contact with the piezoelectric elongate nano-objects 103.

For piezoelectric elongate nano-objects 103 formed by N- or P-doped gallium nitride nanowires, the first electrode 101 may be formed by a layer of gallium nitride or a layer of titanium nitride so as to form an ohmic contact, or a Schottky contact, with the piezoelectric elongate nano-objects 103 depending on the N- or P-type of the doping of the gallium nitride of the nanowires.

Preferably, the interface between the first electrode 101 and the piezoelectric elongate nano-objects 103 is of the Schottky type in order to avoid the passage of a current throughout the piezoelectric elongate nano-objects 103 during the operation of the piezoelectric device 100.

By «interface between an electrode, whether this is the first electrode 101 or, where appropriate, the second electrode 102, and the piezoelectric elongate nano-objects 103», it should be understood the contact, or the contact surface, between the electrode and the piezoelectric elongate nano-objects 103. When this interface is of the ohmic type, it forms an ohmic contact, and when this interface is of the Schottky type, it forms a Schottky contact.

The second electrode 102 may include at least one metallic layer or a doped semiconductor layer allowing:
to ensure the recovery of electric charges if the piezoelectric device 100 is subjected to a load allowing obtaining an electric potential difference in one or several piezoelectric elongate nano-object(s) 103, or
to participate with the first electrode 101 to subject the piezoelectric elongate nano-objects 103 to an electric field in order to deform them.

In general, the first and second electrodes 101, 102 are arranged so that no current crosses the piezoelectric elongate nano-objects 103, that is why the contact of the first electrode 101 with the piezoelectric elongate nano-objects 103 is preferably a Schottky contact. If the first and second electrodes 101, 102 are in contact with the piezoelectric elongate nano-objects 103, at least one of these contacts is a Schottky contact to avoid an electric current being established in the piezoelectric elongate nano-objects 103 resulting in the impossibility of obtaining a piezoelectric effect via these piezoelectric elongate nano-objects 103.

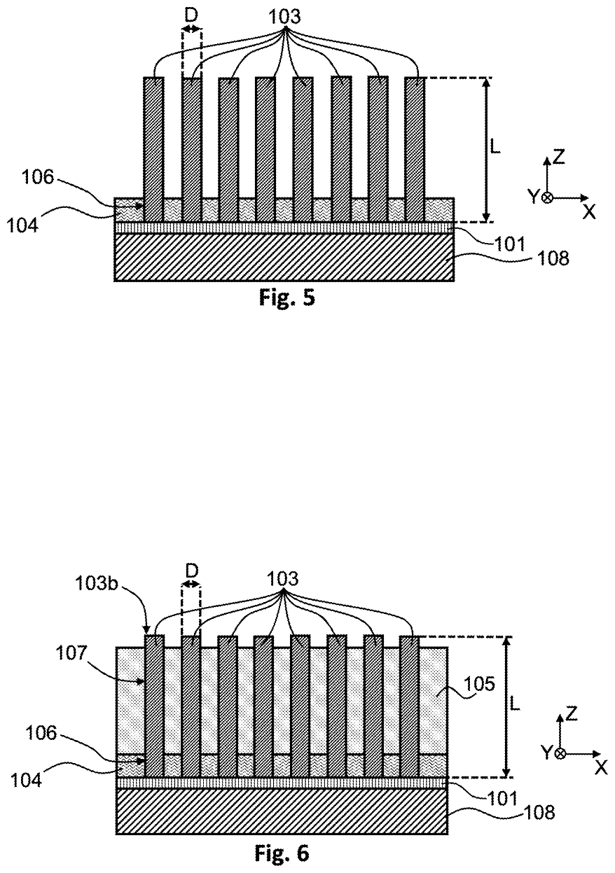

The invention also relates to a method for manufacturing the piezoelectric device 100 whose steps are illustrated as example in FIGS. 4 to 8. The manufacturing method includes a step of forming the piezoelectric elongate nano-objects 103 on the first electrode 101 as shown for example in FIG. 4. The manufacturing method includes, as illustrated for example in FIG. 5, a step of forming the first layer 104 for example by deposition of the first material. This step of forming the first layer 104 is implemented such that the formed first layer 104 surrounds a first longitudinal portion 106 of each of the piezoelectric elongate nano-objects 103. The manufacturing method also includes a step of forming the second layer 105, for example by deposition of the second material, such that the formed second layer 105 surrounds the second longitudinal portion 107 of each of the piezoelectric elongate nano-objects 103 (three different implementations of the formation of this second layer 105 are illustrated respectively in FIGS. 6, 7 and 8). The manufacturing method also includes a step of forming the second electrode 102, for example by deposition, the formed second electrode 102 being arranged so that the piezoelectric elongate nano-objects 103 extend between the first electrode 101 and the second electrode 102 (as shown for example in FIGS. 1 to 3). Of course, the manufacturing method is such that the first layer 104 is arranged between the first electrode 101 and the second layer 105, and that the thickness of the formed first layer 104 is strictly smaller than the thickness of the formed second layer 105. Such a manufacturing method is easy to implement and allows obtaining the piezoelectric device 100 that is both robust and deformable. Of course, the step of forming the second layer 105 is carried out before the step of forming the second electrode 102. Of course, what is applicable for the piezoelectric device applies to the manufacturing method and vice versa.

Each of the deposition of the first material and the deposition of the second material may be implemented by spin coating, by physical vapor deposition, also known by the abbreviation «PVD», by CVD, or by atomic layer deposition, also known by the abbreviation «ALD».

In particular, the piezoelectric device 100 includes the substrate 108 mentioned before and represented in FIGS. 1 to 8. The first electrode 101, and in particular at least one layer forming this first electrode 101, is arranged on this substrate 108. It is then said that the piezoelectric elongate nano-objects 103 are secured, that is to say attached, to this substrate 108 in particular via the first electrode 101.

The substrate 108 may be a rigid substrate made of silicon for example, or of glass, sapphire or a monocrystalline zinc oxide. Advantageously, the substrate 108 is a silicon wafer, also called “wafer” in the field. The substrate 108 may also be a flexible substrate (for example made of polyethylene terephthalate also known under the abbreviation PET, of polyimide, of Kapton® which corresponds to a polyimide film developed by the company DuPont, of poly(methyl methacrylate) also known under the abbreviation PMMA or of polydimethylsiloxane also known under the abbreviation PDMS) if a material growth at low temperature, typically lower than or equal to 200° C., is implemented in order to form the piezoelectric elongate nano-objects 103. Such a growth at low temperature may advantageously be implemented by chemical bath deposition. For example, the growth of the zinc oxide nanowires as piezoelectric elongate nano-objects 103 may be carried out at a low temperature lower than or equal to 100° C.

Preferably, the manufacturing method is such that the first electrode 101 is deposited in the form of one or several layer(s) on the substrate 108 before the step of forming, in particular by growth, the piezoelectric elongate nano-objects 103. In this case, the face of the first electrode 101 opposite the substrate 108 is formed by a metallic or semiconductor material allowing promoting the nucleation of the piezoelectric elongate nano-objects 103 while allowing ensuring, for example, the electrode function later on during the use of the piezoelectric device 100.

Thus, the first electrode 101 preferably includes a surface enabling a growth, in particular orthogonal to the plane of the first electrode 101, of the piezoelectric elongate nano-objects 103. For this purpose, this surface may be delimited by a deposited layer having a cubic crystalline structure textured according to the axis <111> such as a for example a layer of gold. The possible materials of the first electrode 101, and mentioned before for the first electrode 101 to form an ohmic contact or a Schottky contact with the N- or P-doped zinc oxide or gallium nitride nanowires, may be used for the nucleation of these nanowires.

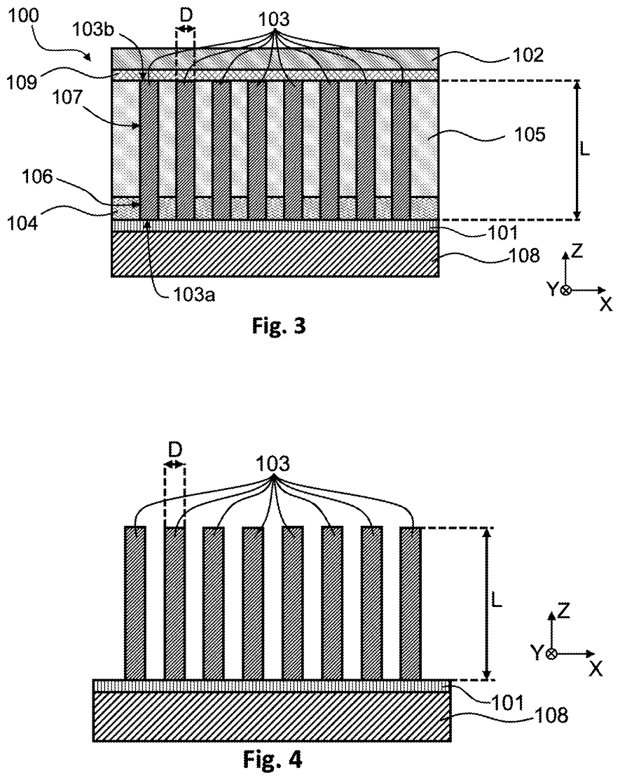

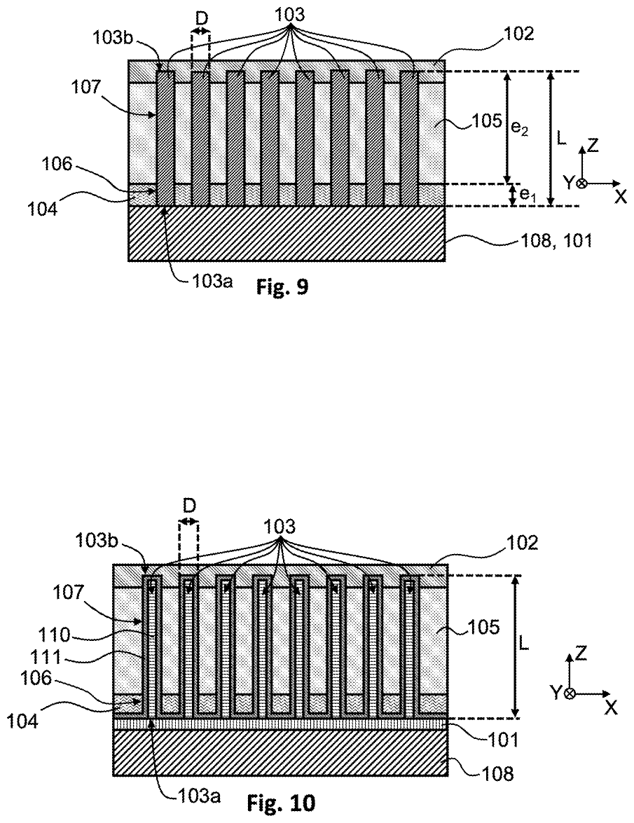

According to one variant represented in FIG. 9, if the substrate 108 is made of a material enabling the nucleation of the piezoelectric elongate nano-objects 103, it could form the first electrode 101. For this purpose, the substrate 108 may be formed by monocrystalline zinc oxide. In this case, the piezoelectric elongate nano-objects 103 can grow directly on the ZnO monocrystal directed according to <0001>. Although the substrate 108, also serving as a first electrode 101 in FIG. 9, is used in the first embodiment like in FIG. 1, it could also be used in the second and third embodiments examples by merging the elements bearing the reference numerals 101 and 108 in FIGS. 2 and 3.

The growth of the piezoelectric elongate nano-objects 103 may be carried out starting from the first electrode 101. According to an embodiment, this growth may be carried using a temporary mask arranged on the first electrode 101, this temporary mask then including through holes which open onto the first electrode 101 thereby enabling the controlled growth of the piezoelectric elongate nano-objects 103 starting from the first electrode 101 and throughout the temporary mask. The temporary mask may be made by a conventional lithography technique or by DNA (abbreviation of DeoxyriboNucleic Acid) origami for which it is possible to obtain pattern sizes of a few nanometers. Of course, this temporary mask is removed before forming the first layer 104.

Preferably, the Young's modulus of the first material is higher than or equal to 5 GPa and even more preferably the Young's modulus of the first material is higher than or equal to 25 GPa. This allows obtaining a proper holding of the piezoelectric elongate nano-objects 103 to one another and in particular with respect to the first electrode 101.

To form, and in particular constitute, the first layer 104, the first material may be selected amongst: a hydrogen silsesquioxane (also known under the abbreviation HSQ) for example having undergone an annealing at a temperature higher than or equal to 250° C. and advantageously higher than or equal to 350° C. (the annealing may be carried out for a few minutes under air), silicon dioxide such as SiO₂ or its non-stoichiometric derivatives, alumina such as Al₂O₃ or its non-stoichiometric derivatives, and a silicon nitride such as Si₃N₄ or its non-stoichiometric derivatives. Such materials have a Young's modulus adapted to ensure the function of a rigid matrix for holding the piezoelectric elongate nano-objects 103. The hydrogen silsesquioxanes having undergone an annealing at a temperature higher than or equal to 350° C. could have a Young's modulus comprised between 5 GPa and 80 GPa. The silicon dioxide may have a Young's modulus comprised between 46 GPa and 92 GPa. The alumina may have a Young's modulus comprised between 300 GPa and 530 GPa. The silicon nitride may have a Young's modulus comprised between 100 GPa and 325 GPa.

Preferably, the Young's modulus of the second material is strictly lower than 5 GPa and even more preferably the Young's modulus of the second material is lower than or equal to 3 GPa. This allowing reinforcing the mechanical stability of the piezoelectric elongate nano-objects 103 and therefore of the array of nano-objects, while conferring a freedom of deformation on each of these piezoelectric elongate nano-objects 103 and therefore on the array of nano-objects during the use of the piezoelectric device 100.

To form, and in particular constitute, the second layer 105, the second material may be selected amongst: a poly(methyl methacrylate) (also known under the abbreviation PMMA), a hydrogen silsesquioxane for example having undergone an annealing at a temperature strictly lower than 250° C. and carried out for a few minutes under air, a SU-8 resin, a polydimethylsiloxane (also known under the abbreviation PDMS) which may for example be untreated or be treated under an oxygen plasma, a parylene C, and a resin based on an organic polymer and containing silicon. Such materials have a Young's modulus adapted to form the second layer 105.

The poly(methyl methacrylate) may have a Young's modulus in the range of 2.5 GPa. The hydrogen silsesquioxane having undergone an annealing at a temperature strictly lower than 250° C. may have a Young's modulus strictly lower than 5 GPa. The SU-8 resin may have a Young's modulus in the range of 2.2 GPa. The untreated PDMS may have a Young's modulus in the range of 2 MPa. The PDMS treated under an oxygen plasma may have a Young's modulus which may range up to 1.5 GPa. The parylene C may have a Young's modulus in the range of 2.5 GPa. In the present paragraph, by «in the range of a value», it should be understood that value within a range of more or less 20%.

The SU-8 resin is a negative photosensitive resin. A SU-8 resin from the SU-8 2000 series for example from the company Kayaku Advanced Materials or a SU-8 GM 10xx resin from the company Gersteltec Engineering Solutions could be used.

As regards the first and second materials defined before, it should be understood in particular that within the piezoelectric device 100:
each of the first and second materials is free of solvent which, in the case where the solvent was initially present in the considered material, might have evaporated completely, for example by heat treatment, during the manufacture of the piezoelectric device 100,
each of the first and second materials is in a state at least partially cross-linked by heat treatment carried out during the manufacture of the piezoelectric device 100.

Preferably, the thickness of the first layer 104 is smaller than or equal to 20%, and advantageously smaller than or equal to 5%, of the length L of the piezoelectric elongate nano-objects 103. This has the technical advantage of ensuring a proper holding of the piezoelectric elongate nano-objects 103 in particular with respect to the first electrode 101 at the level of which the first layer 104 is arranged, while leaving a longer portion of each of the piezoelectric elongate nano-objects 103, not held by this first layer 104 able to be deformed during the use of the piezoelectric device 100. The thickness of the first layer 104 may be larger than or equal to 5 nm.

According to the first embodiment, as illustrated for example in FIGS. 1 and 9, the length L of each of the piezoelectric elongate nano-objects 103 is strictly larger than the sum of the thickness e₁ of the first layer 104 and of the thickness e₂ of the second layer 105. The structure of the piezoelectric device 100 according to this first embodiment is a Schottky structure, the Schottky structure has the advantage of having the lowest impedance. According to this first embodiment, each of the first electrode 101 and the second electrode 102 is in contact with the piezoelectric elongate nano-objects 103. Henceforth, at least one of the first and second electrodes 101, 102 forms a Schottky contact with the piezoelectric elongate nano-objects 103.

To obtain the piezoelectric device 100 according to this first embodiment, the step of forming the second layer 105 is such that it leaves the second longitudinal ends 103b of the piezoelectric elongate nano-objects 103 accessible in order to enable the formation of the second electrode 102 in contact with these second longitudinal ends 103b. In other words, on completion of the formation of the second layer 105, portions of each of the piezoelectric elongate nano-objects 103 protrude from the second layer 105 as shown for example in FIG. 6. Afterwards, the second electrode 102 is formed on the second layer 105 and is in contact with the portions of the piezoelectric elongate nano-objects 103 protruding from the second layer 105 as shown in FIG. 1.

According to the first embodiment, it is possible to distinguish two cases:
if the interface between the first electrode 101 and the piezoelectric elongate nano-objects 103 is of the ohmic type then the interface between the piezoelectric elongate nano-objects 103 and the second electrode 102 must be of the Schottky type,
if the interface between the first electrode 101 and the piezoelectric elongate nano-objects 103 is of the Schottky type, then the interface between the piezoelectric elongate nano-objects 103 and the second electrode 102 could be of the ohmic type or of the Schottky type.

Preferably, according to this first embodiment, the first electrode 103 forms a Schottky contact with the piezoelectric elongate nano-objects 103 and the second electrode 102 forms a Schottky contact with the piezoelectric elongate nano-objects 103. This has the following advantages: having two Schottky contacts, avoiding the leakage currents and having a minimum impedance in comparison with that of the piezoelectric device 100 with the capacitive structure or with the optimized capacitive structure as described hereinafter.

For example, in the first embodiment, if the piezoelectric elongate nano-objects 103 are zinc oxide or gallium nitride nanowires, and if the first electrode 101 forms an ohmic contact with the piezoelectric elongate nano-objects 103, then the second electrode 102 may be made of gold, or palladium or platinum so that this second electrode 102 forms a Schottky contact with the piezoelectric elongate nano-objects 103.

For example, in the first embodiment, if the piezoelectric elongate nano-objects 103 are zinc oxide or gallium nitride nanowires, and if the first electrode 101 forms a Schottky contact with the piezoelectric elongate nano-objects 103, then the second electrode 102 could form an ohmic contact or a Schottky contact with the piezoelectric elongate nano-objects 103, in this case the second electrode 102 could be:
made of aluminum so that this second electrode 102 forms an ohmic contact with the piezoelectric elongate nano-objects 103, or
made of gold, palladium or platinum so that this second electrode 102 forms a Schottky contact with the piezoelectric elongate nano-objects 103.

According to the second embodiment, as illustrated for example in FIG. 2, the length L of each of the elongate nano-objects 103 is strictly smaller than the sum of the thickness e₁ of the first layer 104 and of the thickness e₂ of the second layer 105, the second electrode 102 being at a distance from the piezoelectric elongate nano-objects 103. This has the advantage of avoiding leakage currents. Moreover, this piezoelectric device 100 of the second embodiment has the advantage of being simple to make.

Thus, according to this second embodiment, the second longitudinal end 103b of each of the piezoelectric elongate nano-objects 103 is embedded by the second material of the second layer 105.

In the second embodiment, there is no particular criterion on the nature of the interface between the second layer 105 and the second layer 102. Henceforth, the second electrode 102 may be formed by any metal that could in particular be deposited by PVD.

According to the third embodiment, as illustrated for example in FIG. 3, the first longitudinal ends 103a of the piezoelectric elongate nano-objects 103 are in contact with the first electrode 101, and the second longitudinal ends 103b of the piezoelectric elongate nano-objects 103 are in contact with a third layer 109 of an electrically-insulating material also called dielectric layer 109. The third layer 109 connects the second longitudinal ends 103b to the second layer 102. This particular arrangement including the first, second and third layers 104, 105, 109 has the advantage of obtaining an optimized capacitive structure of the piezoelectric device 100, in particular by allowing improving the collection of charges by the second electrode 102 in comparison with the structure of the second embodiment. In the case where the piezoelectric device 100 is used to apply an electric field deforming the piezoelectric elongate nano-objects 103, the third layer 109 allows avoiding the leakages currents. The third layer 109 may be selected so as to optimize the electrical capacitance formed between the second longitudinal ends 103b of the piezoelectric elongate nano-objects 103 and the second electrode 102, this optimization may be done through the selection of the material forming the third layer 109 and the thickness of the third layer 109. Of course, the third layer 109 is made of a material different from the second material and is in contact with the second layer 105.

For this third embodiment, there is no particular criterion on the nature of the interface between the third layer 109 and the second layer 102. Henceforth, the second electrode 101 may be formed by any metal that could in particular be deposited by PVD.

The electrically-insulating material of the third layer 109 may have a high relative permittivity εᵣ, that is to say higher than or equal to 3.9. In particular, the electrically-insulating material of the third layer 109 may be selected amongst an aluminum oxide like alumina such as Al₂O₃ or its non-stoichiometric derivatives, a silicon nitride such as for example Si₃N₄ or its non-stoichiometric derivatives, or a hafnium oxide such as HfO₂ or its non-stoichiometric derivatives. This allowing in particular improving the collection of charges by the second electrode 102 during the use of the piezoelectric device 100.

The thickness of the third layer 109 may be comprised between 10 nm and 100 nm, this thickness allowing in particular achieving the aforementioned optimization.

Because of the presence of the third layer 109, and in particular of its relative permittivity, the Schottky contact between the piezoelectric elongate nano-objects 103 with the first electrode 101 is not necessary because the third layer 109, alone, allows avoiding the establishment of a current crossing the piezoelectric elongate nano-objects 103 during the use of the piezoelectric device 100.

In the first, second and third embodiments, the second electrode 102 may include two successive layers (not represented). For example, the second electrode 102 may include a layer of titanium or chromium on which a metal layer is arranged such as a layer of gold or any metal that could be deposited by PVD. The layer of titanium or chromium is closer to the first electrode 101 than the metal layer. The layer of titanium or chromium may serve as an attaching layer for the metal layer deposited afterwards on this layer of titanium or chromium. For example, the layer of titanium or chromium may have a thickness comprised between a few nanometers and 50 nm and the layer of gold may have a thickness comprised between a few nanometers and 100 nm. In particular, in the first embodiment, one of the two successive layers of the second electrode 102 is in contact with the piezoelectric elongate nano-objects 103 and determines, by its nature, whether the contact between the piezoelectric elongate nano-objects 103 and the second electrode 102 is an ohmic contact or a Schottky contact.

It results from what has been described before that the thickness of the second layer 105 depends on the embodiment of the piezoelectric device 100. For example, if the second electrode 102 is in contact with the piezoelectric elongate nano-objects 103 (FIG. 1), then the second layer 105 could be setback from the second longitudinal ends 103b by a distance comprised between a few tens of nanometers and 100 nm. For example, if the second layer 105 covers the second longitudinal ends 103b (FIG. 2), then the second material thickness in the continuity of the second longitudinal ends 103b could be comprised between a few tens of nanometers and a few hundreds of nanometers, this excess thickness allowing adjusting the electrical capacitance of the piezoelectric device 100. In the case where the third layer 109 is present (FIG. 3), the thickness of the second layer 105 could be such that the second layer 105 is setback from the second longitudinal ends 103b of the piezoelectric elongate nano-objects 103 by a few nanometers to a few tens of nanometers: in this case, each of the piezoelectric elongate nano-objects 103 protrudes from the second layer 105 by a few nanometers to a few tens of nanometers. In any case, the thickness of the second layer 105 could be adjusted after deposition of the second material by chemical etching, advantageously by plasma, of the deposited second material.

In the case where the piezoelectric elongate nano-objects 103 do not feature a core-shell structure, each could have a diameter comprised between a few tens of nanometers and a few hundreds of nanometers.

As mentioned before, the piezoelectric elongate nano-objects 103 may be nanowires having a core-shell structure (FIGS. 10 to 12). Each of these nanowires with a core-shell structure includes a core 110 forming the core of the core-shell structure and an electrical passivation layer 111 covering the core and forming the shell of the core-shell structure. Thus, each passivation layer 111 is arranged on a corresponding core 110. Herein, only one portion of each of the piezoelectric elongate nano-objects 103, formed by the core 110, is made of a piezoelectric material. Thus, the cores of the piezoelectric elongate nano-objects 103 may for example be made of gallium nitride or zinc oxide. Each electrical passivation layer 111 is made of, that is to say formed by, an electrical passivation material selected amongst: an aluminum nitride such as AlN or its non-stoichiometric derivatives, an aluminum oxide such as for example alumina such as Al₂O₃ or its non-stoichiometric derivatives, a hafnium oxide such as HfO₂ or its non-stoichiometric derivatives, or a titanium oxide such as TiO₂ or its non-stoichiometric derivatives. Each passivation layer 111 may have a thickness comprised between a few nanometers and 100 nm. Each core 110 may have a diameter comprised between a few tens of nanometers and a few hundreds of nanometers. In particular, the core 110 of each of the piezoelectric elongate nano-objects 103 is in contact with the first electrode 101 as it could be seen in FIGS. 10 to 12 which respectively represent FIGS. 1 to 3 for which each of the piezoelectric elongate nano-objects 103 is represented in the form of a nanowire having a core-shell structure. Thus, the step of forming the piezoelectric elongate nano-objects 103 may include a step of growing the cores 110 like simple nanowires would grow for example by nucleation starting from the first electrode 101, and then a step of conformal deposition of the electrical passivation material intended to form the electrical passivation layers 111 on the cores 110 obtained by growth. Afterwards, the first and second layers 104, 105 may be successively formed by depositing:
the first layer 104 between the piezoelectric elongate nano-objects 103 and on the electrical passivation material deposited on the first electrode 101 upon the formation of the electrical passivation layers 111, this passivation material at the base of each of the piezoelectric elongate nano-objects 103 contributes to the mechanical holding of said base, then
the second layer 105 on the first layer 104.

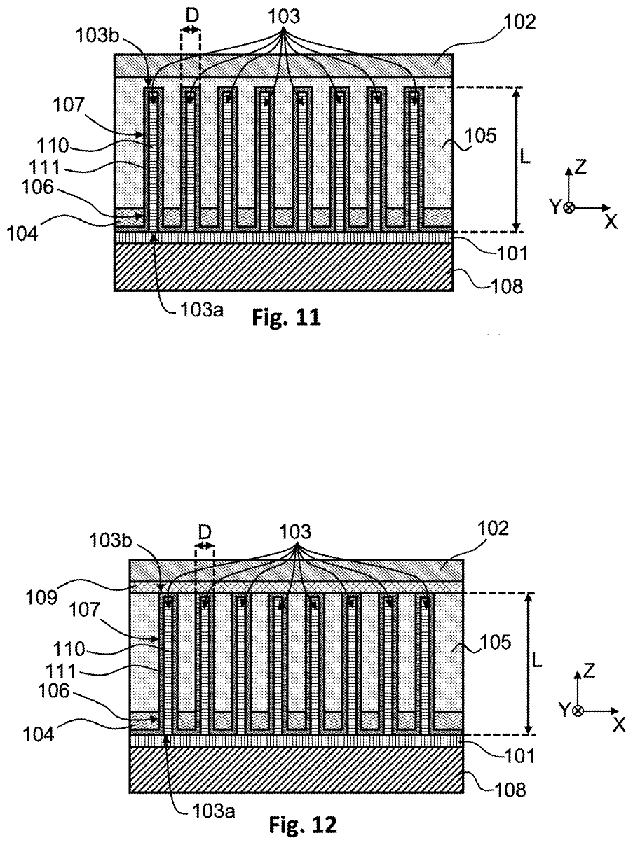

The formation of the second layer 102 may be as described before. In FIG. 10, the piezoelectric device 100 is according to the first embodiment for which the second longitudinal ends 103b are formed by electrical passivation material in contact with the second electrode 102. In FIG. 11, the piezoelectric device 100 is according to the second embodiment for which the second longitudinal ends 103b are formed by electrical passivation material and are at a distance from the second electrode 102 as they are embedded by the second layer 105. In FIG. 12, the piezoelectric device 100 is according to the third embodiment for which the second longitudinal ends 103b are formed by electrical passivation material in contact with the third layer 109.

In case of presence of the electrical passivation layers 111, the first layer 104 is separated from the first electrode 101 by electrical passivation material with a thickness corresponding to the thickness of the passivation layers 111.

The first layer 104 may be in contact with the first electrode 101, in this case the piezoelectric elongate nano-objects 103 could be simple nanowires or nanotubes.

In general, whether the first layer 104 is in contact with the first electrode 101 or separated from the first electrode 101 by the electrical passivation material, it is considered as being at the level, or on the side, of the first longitudinal ends 103a.

In the case where the piezoelectric elongate nano-objects 103 are nanotubes, these are for example of zinc oxide nanotubes or gallium nitride nanotubes. Each of the nanotubes could have an outer diameter comprised between 100 nm and a few hundreds of nanometers, and a wall thickness comprised between a few nanometers and a few tens of nanometers, this wall allowing defining the outer diameter and an inner diameter of the corresponding nanotube. For example, each of the piezoelectric elongate nano-objects 103 may formed by a gallium nitride nanotube having an inner diameter comprised between 30 nm and 200 nm, and an outer diameter comprised between 35 nm and 250 nm defined for example using a nanotube wall with a thickness comprised between 5 nm and 50 nm.

The piezoelectric device 100 as described is intended for an industrial application in the field of energy recovery by piezoelectric effect. The recovered energy, in the form of an electrical signal, could be used in the context of a piezoelectric nanogenerator (in this case the piezoelectric device 100 is optimized to recover energy) or in the context of a pressure sensor (in this case the piezoelectric device 100 is optimized to have a sensitivity adapted to determine the measured pressure afterwards).

In general, in the case where the piezoelectric elongate nano-objects 103 are made of gallium nitride or zinc oxide, the gallium nitride or the zinc oxide could be doped. Typically, gallium nitride is generally less naturally doped than zinc oxide, zinc oxide being generally N-doped. An intentional doping of the piezoelectric elongate nano-objects 103 could be carried out to compensate for the natural doping, this natural doping might reduce the piezoelectric effect of the piezoelectric elongate nano-objects 103, in order to improve this piezoelectric effect.

The piezoelectric device 100 as described may also find an industrial application in the field of haptic feedback. Thus, the piezoelectric device 100 could be a haptic device allowing replicating touch feeling for example for tactile interface. In this case, the first electrode 101 and the second electrode 102 allow applying an electric field to deform the piezoelectric elongate nano-objects 103 in order to ensure the desired haptic feedback.

In other words, the piezoelectric device 100 could form a pressure sensor, a piezoelectric nanogenerator or a haptic device.

1. A piezoelectric device including:
a first electrode,
a second electrode,
piezoelectric elongate nano-objects in contact with the first electrode, the piezoelectric elongate nano-objects extending between the first electrode and the second electrode,
a first layer of a first material, the first material being electrically-insulating, the first layer surrounding a first longitudinal portion of each of the piezoelectric elongate nano-objects,
wherein:
the piezoelectric device includes a second layer of a second material, the second material being electrically-insulating, the second layer surrounding a second longitudinal portion of each of the piezoelectric elongate nano-objects,
the first layer is arranged between the first electrode and the second layer,
the thickness of the first layer is strictly smaller than the thickness of the second layer,
the first material has a Young's modulus strictly higher than the Young's modulus of the second material.

2. The piezoelectric device according to claim 1, wherein the Young's modulus of the first material is higher than or equal to 5 GPa.

3. The piezoelectric device according to claim 2, wherein the Young's modulus of the first material is higher than or equal to 25 GPa.

4. The piezoelectric device according to claim 1, wherein the first material is selected amongst: a hydrogen silsesquioxane, silicon dioxide, alumina and a silicon nitride

5. The piezoelectric device according to claim 1, wherein the Young's modulus of the second material is strictly lower than 5 GPa.

6. The piezoelectric device according to claim 1, wherein the second material is selected amongst: poly(methyl methacrylate), a hydrogen silsesquioxane, a SU-8 resin, a polydimethylsiloxane, a parylene C, and a resin based on an organic polymer and containing silicon.

7. The piezoelectric device according to claim 1, wherein each piezoelectric elongate nano-object has an aspect ratio equal to L/D, with L being the length of said piezoelectric elongate nano-object and D being the maximum transverse dimension of said piezoelectric elongate nano-object, the aspect ratio being higher than or equal to 5 and D being smaller than or equal to 500 nm.

8. The piezoelectric device according to claim 7, wherein D is smaller than or equal to 50 nm.

9. The piezoelectric device (100) according to claim 1, wherein:
the length of each of the elongate nano-objects is strictly larger than the sum of the thickness of the first layer and of the thickness of the second layer,
the second electrode is in contact with the piezoelectric elongate nano-objects,
at least one of the first and second electrodes forms a Schottky contact with the piezoelectric elongate nano-objects.

10. The piezoelectric device according to claim 1, wherein the length of each of the piezoelectric elongate nano-objects is strictly smaller than the sum of the thickness of the first layer and of the thickness of the second layer and in that the second electrode is at a distance from the piezoelectric elongate nano-objects.

11. The piezoelectric device according to claim 1, wherein each of the piezoelectric elongate nano-objects includes a first longitudinal end and a second longitudinal end, the first longitudinal ends being in contact with the first electrode and the second longitudinal ends being in contact with a third layer of an electrically-insulating material, the third layer connecting the second longitudinal ends to the second electrode.

12. The piezoelectric device according to claim 11, wherein the electrically-insulating material of the third layer has a relative permittivity higher than or equal to 3.9.

13. The piezoelectric device according to claim 12, wherein the electrically-insulating material of the third layer is selected amongst: an aluminum oxide, a silicon nitride and a hafnium oxide.

14. The piezoelectric device according to claim 1, wherein the piezoelectric elongate nano-objects are:
zinc oxide or gallium nitride nanowires, or
zinc oxide or gallium nitride nanotubes, or
nanowires each including a core made of zinc oxide or gallium nitride, and an electrical passivation layer arranged on said core.

15. The piezoelectric device according to claim 1, wherein the thickness of the first layer is smaller than or equal to 20% of the length of the piezoelectric elongate nano-objects.

16. The piezoelectric device according to claim 1, wherein it includes a substrate and in that the first electrode is arranged on the substrate or is formed by the substrate.

17. The piezoelectric device according to claim 1, wherein it forms a pressure sensor, a piezoelectric nanogenerator or a haptic device.

18. A method for manufacturing a piezoelectric device, the manufacturing method including:
a step of forming piezoelectric elongate nano-objects on a first electrode,
a step of forming a first layer of a first material so that the formed first layer surrounds a first longitudinal portion of each of the piezoelectric elongate nano-objects, the first material being electrically-insulating,
a step of forming a second electrode, the formed second electrode being arranged so that the piezoelectric elongate nano-objects extend between the first electrode and the second electrode,
wherein:
it includes a step of forming a second layer of a second material so that the formed second layer surrounds a second longitudinal portion of each of the piezoelectric elongate nano-objects, the second material being electrically-insulating,
the first layer is arranged between the first electrode and the second layer,
the thickness of the formed first layer is strictly smaller than the thickness of the formed second layer,
the first material has a Young's modulus strictly higher than the Young's modulus of the second material.
